(19) United States
(12) Patent Application Publication
(10) Pub. No.: US 2020/0279724 A1
(43) Pub. Date: Sep. 3, 2020

(54) FILM FORMATION DEVICE

(71) Applicant: Shincron Co., Ltd., Kanagawa (JP)

(72) Inventors: Ekishu NAGAE, Kanagawa (JP); Takuya SUGAWARA, Kanagawa (JP); Takaaki AOYAMA, Kanagawa (JP)

(21) Appl. No.: 16/497,715

(22) PCT Filed: Apr. 6, 2018
(86) PCT No.: PCT/JP2018/014735

§ 371 Date: Sep. 25, 2019

(30) Foreign Application Priority Data
Apr. 10, 2017 (CN) 201710228584.1

(51) Int. Cl. H01J 37/34; C23C 14/00; C23C 14/35

(52) U.S. Cl. CPC H01J 37/3435; H01J 37/3417; H01J 37/3405; H01J 2237/20214; C23C 14/35; H01J 2237/332; H01J 2237/201; C23C 14/0068

(57) ABSTRACT

The present invention discloses a film formation device. The film formation device includes a vacuum chamber, an evacuation mechanism communicating with an interior of the vacuum chamber, a substrate holding means capable of holding a plurality of substrates, and a film formation area located in the interior of the vacuum chamber. The film formation area allows sputter ions to be emitted from a target by sputtering and arrive at the substrates. The film formation device further includes an isolation means located in the vacuum chamber. The isolation means isolates the film formation area from other areas in the vacuum chamber. The isolation means is arranged such that the film formation area communicates with an exterior of the film formation area.

### TECHNICAL FIELD

The present invention relates to a film formation device that performs sputtering to form a thin film on a substrate.

The present application claims priority based on Chinese Patent Application No. 201710228584.1 filed on Apr. 10, 2017. For those designated countries which permit the incorporation by reference, the content described and/or illustrated in the above application is incorporated by reference in the present application as part of the description and/or drawings of the present application.

### BACKGROUND ART

Plasma treatment such as formation of a thin film on a substrate or surface modification or etching of the formed thin film is currently performed using a reactive gas plasmatized in a vacuum chamber. For example, a technique is known which includes forming a thin film composed of an incomplete reaction product of metal on a substrate using the sputtering technique and bringing the thin film composed of the incomplete reaction product into contact with a plasmatized gas to form a thin film composed of a metal compound.

### SUMMARY OF INVENTION

### Problems to be Solved by Invention

FIG. 1 illustrates a schematic view of the structure of a film formation processing section (film formation area) 100 in a sputter film formation device having a conventional structure. The film formation device having a conventional structure includes a vacuum chamber provided therein with a film formation area and a reaction area. In the film formation area 100, a target 102 composed of metal is sputtered under an atmosphere of an operation gas, and deposition of sputtered particles and plasma treatment by sputtering plasma are performed to form a continuous or discontinuous intermediate thin film composed of metal or of an incomplete reaction product of metal, while in the reaction area, electrically neutral active species of a reactive gas in plasma generated under an atmosphere including the reactive gas is brought into contact with the intermediate thin film on a substrate S, which is coming close, and reacted with the intermediate thin film to convert it into a continuous ultrathin film composed of an complete reaction product of metal.

In order for the reaction area and the film formation area 100 to be separated from each other spatially and in the pressure inside the vacuum chamber, a separator 101 (or referred to as a cover) is usually provided on the inner wall surface of the vacuum chamber. The separator is provided in each of the reaction area and the film formation area 100 so as to be relatively independent inside the vacuum chamber. In a specific case, different film formation areas 100 may be provided in the vacuum chamber so as to sputter two different substances. Similarly, in order to separate the two film formation areas 100 spatially and in the pressure inside the vacuum chamber, it is also necessary to make the reaction area independent by the separator 101 inside the vacuum chamber.

As illustrated in FIG. 1, the separator 101 at present is in the form of a closed plate. The reason that such a form is employed is because this structure is for separating between internal areas of the vacuum chamber (between the reaction area and the film formation area 100 or between different film formation areas 100) and maintaining independent operations in respective processes to avoid the influence on the quality of film formation due to mutual interference between the different processes.

In the film formation area 100, a continuous or discontinuous intermediate thin film composed of metal or of an incomplete reaction product of metal is formed on the film formation surface of the substrate S by the deposition of sputtered particles, which are formed by sputtering the target 102, and the plasma treatment by the sputtering plasma. To suppress the increase in scattering on the thin film, it is necessary to reduce the obliquely incident components in the film formation area 100. By employing the separator 101, the separator 101 can block the sputtered particles, which move straight ahead, from being mixed into the thin film as the obliquely incident components and can suppress the increase in scattering on the thin film.

On the basis of the above idea, the film formation device employing the conventional sputtering technique still uses the closed-type separator 101 or closed-type cover 101. The inventors of the present invention have found that the existence of the closed-type separator 101 can reduce the sputtered particles moving straight ahead as the obliquely incident components, but the internal pressure increases in the film formation area 100 due to the closed environment (relative closure) formed by the closed-type separator 101 so that the impacts and collisions readily occur between the particles, and the obliquely incident components due to the particle collision of the sputtered particles increase to deteriorate the effect of reducing the scattering on the thin film.

In consideration of the above technical issues, it is necessary for the present invention to provide a film formation device so as to improve the effect of reducing the scattering on a thin film.

### Means for Solving Problems

(1) The film formation device according to the present invention comprise: a vacuum chamber; an evacuation mechanism communicating with an interior of the vacuum chamber; a substrate holding means capable of holding a plurality of substrates; a film formation area located in the interior of the vacuum chamber, the film formation area allowing sputtered particles to be emitted from a target by sputtering and arrive at the substrates; and an isolation means located in the vacuum chamber, the isolation means isolating the film formation area from an area in the vacuum chamber, the isolation means having a mechanism for allowing the film formation area to communicate with an exterior of the film formation area.

(2) In the film formation device according to the present invention, the isolation means may be provided on an inner wall of the vacuum chamber.

(3) In the film formation device according to the present invention, the isolation means may be provided at a predetermined position of the inner wall of the vacuum chamber so that an extending direction of the isolation means is orthogonal to a direction along the inner wall.

(4) In the film formation device according to the present invention, the isolation means may extend along a straight line from the inner wall of the vacuum chamber toward the substrate holding means.

(5) In the film formation device according to the present invention, the isolation means may include two separators provided opposite to each other and the film formation area may be located between the two separators.

(6) In the film formation device according to the present invention, at least one of the separators may be provided with a communication gap for communicating between the film formation area and the exterior of the film formation area.

(7) In the film formation device according to the present invention, the at least one of the separators may include a plurality of baffles arranged along the direction from the inner wall of the vacuum chamber to the substrate holding means and the communication gap may be located between adjacent two of the baffles.

(8) In the film formation device according to the present invention, the plurality of baffles may be arranged in parallel along the direction from the inner wall of the vacuum chamber to the substrate holding means.

(9) In the film formation device according to the present invention, the baffles may be inclined toward the substrate holding means from one end parts to other end parts of the baffles.

(10) In the film formation device according to the present invention, an inclination angle θ of the baffles with respect to a plane along the inner wall of the vacuum chamber may satisfy 0<θ≤90°.

(11) In the film formation device according to the present invention, the baffles may have a length from one end parts to other end parts of the baffles shorter than a width of the target or a distance from the target to the substrates.

(12) In the film formation device according to the present invention, at least two of the baffles may have an equal length from one end parts to other end parts of the baffles or reduce in size along a direction from the target to the substrates.

(13) In the film formation device according to the present invention, a distance between adjacent two of the baffles may be shorter than a length from one end parts to other end parts of the baffles.

(14) In the film formation device according to the present invention, a distance between adjacent two of the baffles may be equal.

(15) In the film formation device according to the present invention, a distance from one end part of the baffle closest to the substrate holding means to the substrate holding means may be more than 0 and less than 0.9 times the distance from the target to the substrates.

(16) In the film formation device according to the present invention, at least a part of a surface of at least one of the separators may be a rough surface.

(17) In the film formation device according to the present invention, the rough surface may be formed by twin wire arc spray and roughness of the rough surface is one tenth or less of a thickness of a twin wire arc spray treated layer.

This can reduce the obliquely incident components due to particle collision. Thus, by employing the film formation device of the present invention, the obliquely incident components can be drastically suppressed, and the effect of reducing the scattering on the thin film can be well improved.

Specific embodiments of the present invention are disclosed in detail with reference to the following description and the accompanying drawings, and schemes in which the principles of the present invention can be employed are clearly described. It should be appreciated that the embodiments of the present invention are not limited in the scope. The embodiments of the present invention encompass many variations, modifications, and equivalents within the scope of the appended claims. Features described and/or illustrated in one embodiment can be used in one or more other embodiments in the same or similar scheme, combined with features in other embodiments, or substituted with features in other embodiments. It is to be noted that the term “comprise/comprising” as used herein refers to the presence of a feature, an integral, a step, or a module, but does not exclude the presence or addition of one or more other features, integrals, steps, or modules.

### Effect of Invention

According to the present invention, the scattering on the thin film can be reduced.

### BRIEF DESCRIPTION OF DRAWINGS

FIG. 1 is a schematic view of the structure of a film formation area in a sputtering film formation device having a conventional structure.

FIG. 2 is a partial cross-sectional view of a film formation device in an embodiment of the present invention.

FIG. 3 is a partial longitudinal cross-sectional view along line II-II in FIG. 2.

FIG. 4 is a structural view of a film formation area in FIG. 2.

FIG. 5 is a structural schematic view of a film formation device in an embodiment.

FIG. 6 is a structural view of a separator in FIG. 2.

### MODE(S) FOR CARRYING OUT THE INVENTION

In order for a person skilled in the art to better understand the technical content in the present invention, the technical content in the embodiments of the present invention will be described below with reference to the accompanying drawings in the embodiments of the present invention. The embodiments to be described may not necessarily be all the embodiments of the present invention and may be part of the embodiments.

It is to be noted that when an element is referred to as being “provided” on or in another element, the element can be directly located on or in the other element or can also be present indirectly. When an element is considered to be “connected” to another element, the element can be directly connected to the other element or can also be present indirectly. The terms “vertical,” “horizontal,” “left,” “right,” and similar terms as used herein are merely for descriptive purposes and are not intended to state that the relevant embodiment is one and only embodiment.

Unless otherwise defined, all the technical and scientific terms as used herein have the same meanings as commonly understood by a person skilled in the art. As used herein, the terms used in the description of the present invention are merely for the purpose of describing specific embodiments and are not intended to limit the present invention. The term “and/or” as used herein includes a listed relevant item or any and all of combinations of two or more listed relevant items.

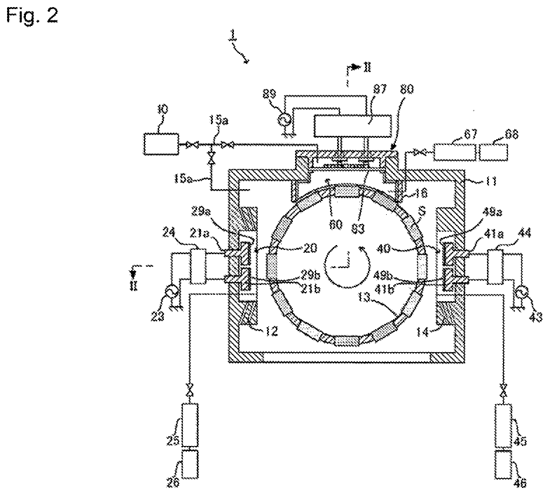

A film formation device 1 according to an embodiment of the present invention will be described with reference to FIGS. 2 to 6. In the present embodiment, the film formation device 1 comprises a vacuum chamber 11, an evacuation mechanism that communicates with the interior of the vacuum chamber 11, a substrate holding means 13 that can hold a plurality of substrates S, film formation areas 20 and 40 that are located in the interior of the vacuum chamber 11 and allow sputter ions to be emitted from targets 29 by sputtering and to arrive at the substrates S, and an isolation means that is located in the vacuum chamber 11 and isolates the film formation areas 20 and 40 from other areas in the vacuum chamber 11. The isolation means is disposed such that the film formation areas 20 and 40 communicate with the exterior of the film formation areas 20 and 40.

By providing the isolation means in the film formation device 1 according to the present embodiment, it is possible to reduce the obliquely incident components to the thin films due to the sputtered particles moving straight ahead. Moreover, the isolation means allows the film formation areas 20 and 40 to communicate with the exterior of the film formation areas 20 and 40 and also allows the interiors of the film formation areas 20 and 40 to communicate with the exterior in the vacuum chamber 11, and the gases in the film formation areas 20 and 40 can flow through the isolation means to suppress the increase in the internal pressures of the film formation areas 20 and 40. This can reduce the obliquely incident components due to the particle collision. Thus, the film formation device 1 of the present embodiment can drastically suppress the obliquely incident components to reduce the scattering on the thin films. In the present embodiment, the film formation device 1 may be further provided with a reaction area 60, one or more cathode electrodes, one or more sputtering power sources, and a plasma generating means. The reaction area 60 is formed in the vacuum chamber 11 and disposed to be spatially separated from the film formation areas 20 and 40. The film formation areas 20 and 40 and the reaction area 60 are usually arranged upstream and downstream in the moving direction of the substrate holding means 13. In consideration that the movement of the substrate holding means 13 is usually circulating or reciprocating movement, the specific order of the upstream and downstream arrangement of the film formation areas 20 and 40 and the reaction area 60 is not particularly limited in the present embodiment.

In the present embodiment, the cathode electrodes are used to mount the targets 29.

The sputtering power sources are used to generate sputtering discharge in the film formation areas 20 and 40 facing the surfaces to be sputtered of the targets 29. The plasma generating means is used to generate different plasma in the reaction area 60 than the sputtering plasma by the sputtering discharge generated in the film formation areas 20 and 40.

In the present embodiment, the film formation device 1 is configured such that the targets 29 are mounted on the cathode electrodes, the sputtering power sources are turned on to operate the plasma generating means, a number of substrates S are held on the outer circumferential surface of the substrate holding means 13, and the substrate holding means 13 is rotated thereby to allow the sputtered particles emitted from the targets 29 to arrive at and deposit on the substrates S having moved to the film formation areas 20 and 40, while at the same time, plasma treatment is performed to make the ions in the sputtering plasma collide with the substrates S or the deposited materials of the sputtered particles to form the intermediate thin films, then plasma retreatment is performed to make the ions in different plasma than the sputtering plasma collide with the intermediate thin films of the substrates S having moved to the reaction area 60 to convert the intermediate thin films to ultrathin films, and thereafter sets of the ultrathin films are stacked to form thin films.

In the present embodiment, the film formation device 1 can further include a driving means. The driving means can rotate the substrate holding means 13. Rotation of the substrate holding means 13 by the driving means allows the substrates S to repeatedly move between predetermined positions in the film formation areas 20 and 40, at which the sputtered particles emitted from the targets 29 by the sputtering plasma arrive, and predetermined positions in the reaction area 60 exposed to plasma different from the sputtering plasma.

The “movement” as referred to in the above invention includes linear movement in addition to curvilinear movement (e.g., circular movement). Therefore, the operation of “moving the substrates S from the film formation areas 20 and 40 to the reaction area 60” includes a form of reciprocating on a linear trajectory connecting between two given points in addition to a form of revolving around a given central axis.

The “rotation” as referred to in the above embodiment includes revolution in addition to literal rotation. Therefore, when simply referring to “rotating around the central axis,” this operation includes a form of revolution around a given central axis in addition to a form of literal rotation around a given central axis.

The “intermediate thin films” as referred to in the above embodiment are films formed by passing through the film formation areas 20 and 40. The term “ultrathin films” is used to prevent confusion with “thin films” because the ultrathin films are deposited more than once to form the final thin films, and this means that the “ultrathin films” are sufficiently thinner than the final “thin films.”

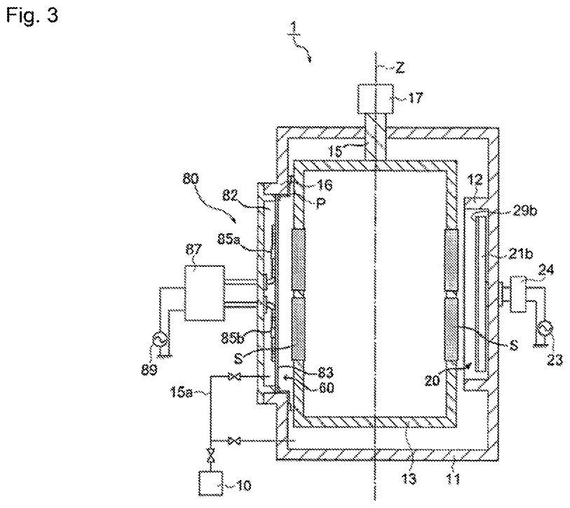

As illustrated in FIGS. 2 and 3, in the present embodiment, the vacuum chamber 11 in a specific form has a chamber main body that surrounds, with its side wall along the vertical direction (up-down direction on the sheet plane of FIG. 3, here and hereinafter), a space in the planar directions (directions orthogonal to the vertical direction, i.e., up-down and right-left directions on the sheet plane of FIG. 2 and the direction perpendicular to the sheet plane of FIG. 3, here and hereinafter). In the present embodiment, the cross section of the chamber main body in the planar directions is rectangular, but may also be in another shape (such as a circular shape), and the shape is not particularly limited. The vacuum chamber 11 can be composed, for example, of a metal such as stainless steel.

In the present embodiment, a hole for a shaft 15 (see FIG. 3) to pass through is formed in the upper part of the vacuum chamber 11 and electrically grounded to the ground potential. The driving means drives the shaft to rotate and the substrate holding means can thereby be rotated together with the shaft. The substrate holding means can rotate about the shaft so that the substrates can repeat movement between the film formation areas and the reaction area. Specifically, the driving means may be a motor 17.

In the present embodiment, the shaft 15 is formed of an approximately pipe-like member and rotatably supported with respect to the vacuum chamber 11 via an insulating member (not illustrated) that is disposed in the hole portion formed in the upper part of the vacuum chamber 11. By being supported with respect to the vacuum chamber 11 via an insulating member composed of an insulator, resin, or the like, the shaft 15 is rotatable relative to the vacuum chamber 11 in a state of being electrically insulated from the vacuum chamber 11.

In the present embodiment, a first gear (not illustrated) is fixed to the upper end side of the shaft 15 located outside the vacuum chamber 11. The first gear meshes with a second gear (not illustrated) on the output side of the motor 17. By driving the motor 17, the rotational driving force is transmitted to the first gear via the second gear, and the shaft 15 is rotated.

In the embodiment illustrated in FIGS. 2 and 3, a cylindrical rotating body (rotary drum) is attached to the lower end part of the shaft 15 located inside the vacuum chamber 11. In the present embodiment, the rotary drum is disposed in the vacuum chamber 11 such that the axis Z extending in the cylinder direction is directed in the vertical direction (Y direction) of the vacuum chamber 11. The rotary drum has a cylindrical shape in the present embodiment, but is not limited to having this shape, and may have a polygonal columnar shape of which the cross section is a polygon, or a conical shape. The rotary drum rotates about the axis Z through the rotation of the shaft 15 which is driven by the motor 17.

The substrate holding means 13 is mounted on the outer side (outer circumference) of the rotary drum. The outer circumference surface of the substrate holding means 13 is provided with a plurality of substrate holding parts (e.g., recesses, not illustrated), which can support the substrates S as film formation objects from the back surfaces of the substrates S (the back surfaces mean the opposite surfaces to the film formation surfaces).

In the present embodiment, the axis (not illustrated: rotation axis) of the substrate holding means 13 and the axis Z (rotation axis) of the rotary drum coincide with each other. Therefore, by rotating the rotary drum about the axis Z, the substrate holding means 13 is in synchronization with the rotation of the drum and rotates together with the rotary drum around the axis Z of the drum.

In the present embodiment, the evacuation mechanism includes a vacuum pump 10. A pipe 15a for evacuation is connected to the vacuum chamber 11. The vacuum pump 10 for evacuating the interior of the vacuum chamber 11 is connected to the pipe 15a, and the degree of vacuum in the vacuum chamber 11 can be adjusted by the vacuum pump 10 and a controller (not illustrated). The vacuum pump 10 can be composed, for example, of a rotary pump, a turbo molecular pump (TMP), or the like.

Sputtering sources and a plasma source 80 (one specific embodiment of the above plasma generating means) are arranged around the substrate holding means 13 which is disposed in the vacuum chamber 11. In the present embodiment illustrated in FIGS. 2 and 3, two sputtering sources and one plasma source 80 are provided, but in the present invention, it suffices that at least one sputtering source is provided, and accordingly at least one film formation area, which will be described later, may be provided.

In the present embodiment, the film formation areas 20 and 40 are formed in front of the sputtering sources. Likewise, the reaction area 60 is formed in front of the plasma source. The film formation areas 20 and 40 are each formed as an area that is surrounded by an inner wall surface 111 of the vacuum chamber 11, a partitioning means (corresponding to a partitioning wall projecting from the inner wall surface 111 of the vacuum chamber 11 toward the substrate holding means), an outer circumferential surface of the substrate holding means 13, and the front surface of each sputtering source, so that the film formation areas 20 and 40 are separated spatially and in the pressure in the interior of the vacuum chamber 11 by the partitioning means, and respective independent spaces are ensured. This configuration which surrounds the film formation areas 20 and 40 corresponds to the isolation means. FIG. 2 exemplifies a case in which two pairs of magnetron electrodes are provided (electrodes 21a and 21b and electrodes 41a and 41b) on the assumption that two different types of substances are sputtered.

Similar to the film formation areas 20 and 40, the reaction area 60 is formed as an area that is surrounded by the inner wall surface 111 of the vacuum chamber 11, a partitioning wall 16 projecting from the inner wall surface 111 toward the substrate holding means 13, the outer circumferential surface of the substrate holding means 13, and the front surface of the plasma source 80, so that the area 60 is also separated spatially and in the pressure from the film formation areas 20 and 40 in the interior of the vacuum chamber 11, and an independent space is ensured. In the present embodiment, the processing in each of the areas 20, 40, and 60 is configured to be independently controllable.

The configuration of each sputtering source is not particularly limited, but in the present embodiment, as a commonly-used one, each sputtering source is configured as a dual cathode type provided with two magnetron sputtering electrodes 21a and 21b (or 41a and 41b) (a specific embodiment of the above cathode electrodes). During the film formation (which will be described later), targets 29a and 29b (or 49a and 49b) are detachably held on one end surfaces of the electrodes 21a and 21b (or 41a and 41b), respectively. An AC power source 23 (or 43) as a power supply means is connected to the other end of each of the electrodes 21a and 21b (or 41a and 41b) via a transformer 24 (or 44) as a power control means that adjusts the electric energy, and the AC power source 23 (or 24) is configured to apply an AC voltage having a frequency of, for example, about 1 kHz to 100 kHz to each of the electrodes 21a and 21b (or 41a and 41b).

A sputtering gas supply means is connected to the front surface of each sputtering source (the front surface refers to each of the film formation areas 20 and 40). In the present embodiment, the sputtering gas supply means includes a gas cylinder 26 (or 46) that stores a sputtering gas and a mass flow controller 25 (or 45) that adjusts the flow rate of the sputtering gas supplied from the cylinder 26 (or 46). The sputtering gas is introduced into the area 20 (or 40) through a pipe. The mass flow controller 25 (or 45) is a device that adjusts the flow rate of the sputtering gas. The sputtering gas from the cylinder 26 (or 46) is introduced into the area 20 (or 40) after adjusting the flow rate by the mass flow controller 25 (or 45).

The configuration of the plasma source 80 is also not particularly limited, but in the present embodiment, the plasma source 80 has a case body 81 fixed so as to close, from the outside, an opening formed in the wall surface of the vacuum chamber 11 and a dielectric plate 83 fixed to the front surface of the case body 81. Thus, the dielectric plate 83 is configured to be fixed to the case body 81 thereby to form an antenna accommodation chamber 82 in an area surrounded by the case body 81 and the dielectric plate 83.

The antenna accommodation chamber 82 is separated from the interior of the vacuum chamber 11. That is, the antenna accommodation chamber 82 and the interior of the vacuum chamber 11 form independent spaces that are in a state of being partitioned by the dielectric plate 83. In addition, the antenna accommodation chamber 82 and the exterior of the vacuum chamber 11 form independent spaces that are in a state of being partitioned by the case body 81. The antenna accommodation chamber 82 is in communication with the vacuum pump 10 through a pipe 15a, so that the vacuum pump 10 can evacuate the interior of the antenna accommodation chamber 82 to a vacuum state.

Antennas 85a and 85b are installed in the antenna accommodation chamber 82. The antennas 85a and 85b are connected to an AC power source 89 via a matching box 87 accommodating a matching circuit. The antennas 85a and 85b receive the supply of power from the AC power source 89 to generate an induction electric field in the interior of the vacuum chamber 11 (in particular, in the area 60) and generate plasma in the area 60. In the present embodiment, the AC power source 89 is configured to apply an AC voltage to the antennas 85a and 85b to generate plasma of a reaction process gas in the area 60. A variable capacitor is provided in the matching box 87 so that the power supplied from the AC power source 89 to the antennas 85a and 85b can be varied.

A reaction process gas supply means is connected to the front surface of the plasma source 80 (reaction area 60). In the present embodiment, the reaction process gas supply means includes a gas cylinder 68 that stores the reaction process gas and a mass flow controller 67 that adjusts the flow rate of the reaction process gas supplied from the cylinder 68. The reaction process gas is introduced into the area 60 through a pipe. The mass flow controller 67 is a device that adjusts the flow rate of the reaction process gas. The reaction process gas from the cylinder 68 is introduced into the area 60 after adjusting the flow rate by the mass flow controller 67.

The reaction process gas supply means is not limited to having the above configuration (i.e., a configuration including one cylinder and one mass flow controller), and can also have a configuration including a plurality of cylinders and a plurality of mass flow controllers (e.g., a configuration including two cylinders that separately store an inert gas and a reactive gas and two mass flow controllers that adjust the flow rate of respective gases supplied from the two cylinders).

In the present embodiment, the isolation means is located in the vacuum chamber 11. Among others, as a preferred embodiment, the isolation means is provided on the inner wall of the vacuum chamber 11. In this case, the isolation means and the case body (the above chamber main body) of the vacuum chamber 11 may have an integral structure, or the isolation means may be connected to the vacuum chamber 11.

The inner wall of the vacuum chamber 11 (the inner wall provided with the isolation means) may be an inner wall 111 (which may be considered as the above inner wall surface 111) located between the top and bottom of the vacuum chamber 11. As will be understood, in the present embodiment, the isolation means may be connected to the top and/or bottom of the vacuum chamber 11 so as to be fixed in the vacuum chamber 11.

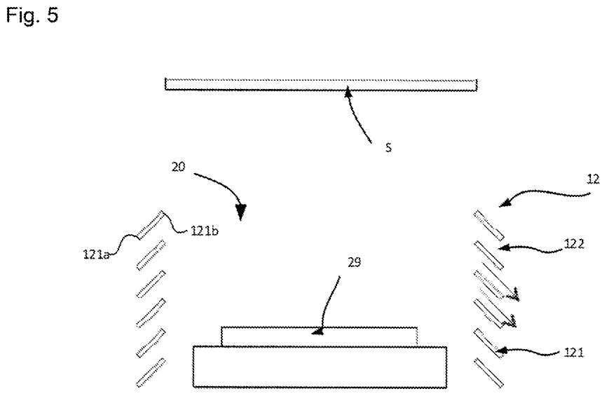

In addition or alternatively, the isolation means may be bridged in the vacuum chamber 11. For example, a bracket may be mounted on the shaft 15 and the bracket and the shaft 15 can be connected to each other by means of bearings. The bracket can remain at rest with respect to the vacuum chamber without affecting the rotation of the shaft 15. The isolation means may be assembled with the bracket. In addition or alternatively, as illustrated in FIG. 5, the bracket can be attached to the inner wall 111 of the vacuum chamber 11 for attachment of the isolation means.

As described above, a number of types of methods for positioning the isolation means in the vacuum chamber 11 are conceivable. It suffices that the isolation means can be flexibly installed in the actual manufacturing and mounting and can isolate (partition) the film formation areas 20 and 40 from other areas in the vacuum chamber 11. The structure for installing the isolation means on the inner wall of the vacuum chamber 11 may be an undetachable connection, for example, of a connection scheme such as welding or swage. In addition or alternatively, the structure for installing the isolation means on the inner wall of the vacuum chamber 11 may be a detachable connection, for example, of a connection scheme such as bolt fastening, screwing, or buckle fastening. As will be understood from this, a number of types of structures for installing the isolation means in the vacuum chamber 11 are conceivable and are not limited at all in the present invention.

In the present embodiment, the isolation means is formed by projecting and extending a part of the inner wall of the vacuum chamber 11. In this case, the isolation means and the vacuum chamber 11 have an integral structure. The integral structure of the isolation means and vacuum chamber 11 may include the following cases. The entire isolation means can be formed by projecting and extending a part of the inner wall of the vacuum chamber 11, and the isolation means as such is an integral structure. Alternatively, the isolation means itself has a plurality of connected and engaged components, and some components are each formed by projecting and extending a part of the inner wall of the vacuum chamber 11 and the other components are assembled with the some components to form the isolation means.

The isolation means can surround the circumferences of the film formation areas 20 and 40 so that the film formation areas 20 and 40 form closed spaces, and at the same time, the isolation means is located between the substrate holding means 13 and the inner wall of the vacuum chamber 11. As illustrated in FIGS. 2 and 3, one end (or one side) of the isolation means far from the inner wall of the vacuum chamber 11 is close to the substrates S on the substrate holding means 13, but a certain gap is formed between the isolation means and the substrates S so as to avoid interference with the reciprocating movement of the substrates S, which follows the substrate holding means 13, and with the formation of thin films. The closed spaces in which the film formation areas 20 and 40 are located are relatively closed and may be separated spatially and in the pressure from other areas.

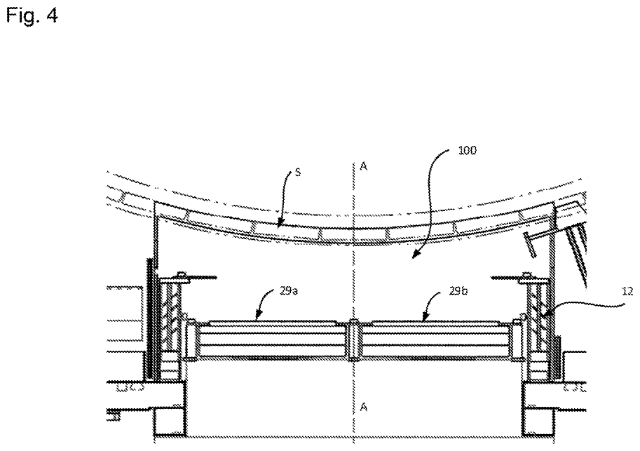

The isolation means extends from the inner wall 111 of the vacuum chamber 11 to the substrate holding means 13, and in an exemplary case, the isolation means may extend along a straight line or along a curved line. The isolation means may also extend between the substrate holding means 13 and the inner wall of the vacuum chamber 11 obliquely with respect to the surface of the inner wall of the vacuum chamber 11. For example, as illustrated in FIGS. 4 and 5, the angle between the extending direction of the isolation means and the up-down direction on the sheet plane (which may be the direction of A-A axis) is larger than 0 degrees and less than 90 degrees.

In the present embodiment, the isolation means extends along a straight line from the inner wall 111 of the vacuum chamber 11 to the substrate holding means 13. In this case, the cross section of the isolation means in the horizontal plane is approximately in an elongated shape as illustrated in FIGS. 2 and 4. Straight lines exist parallel to the longitudinal direction of the elongated cross section.

The extending direction of the isolation means from the inner wall 111 of the vacuum chamber 11 to the substrate holding means 13 may be parallel to the up-down direction on the sheet plane (which is also the direction of A-A axis), or a certain angle may be formed between the extending direction and the up-down direction on the sheet plane. In the present embodiment, the isolation means may be orthogonal to the inner wall 111 of the vacuum chamber 11 or to the inner wall surface 11 at a predetermined position. In this case, as illustrated in FIGS. 2 and 4, the extending direction of the isolation means from the inner wall of the vacuum chamber 11 to the substrate holding means 13 is parallel to the up-down direction on the sheet plane.

In the present embodiment, the isolation means may have two separators 12 and 14 provided opposite to each other. The film formation areas 20 and 40 are located between the two separators 12 and 14. Each of the separators 12 and 14 can be composed of one component or can also be formed by assembling a plurality of components. For example, the separators 12 and 14 may be rectangular plates or may also be formed by arranging a plurality of baffles 121 as described below.

In the present embodiment, the isolation means does not exclude having other isolation portions. As illustrated in FIG. 2, the upper and lower end parts of the two separators 12 and 14 are connected by the separators (or structures isolated in a streak shape, denoted by reference numerals 12 and 14 in FIG. 2 because the structures are also part of the isolation means), and the isolation means of a “mouth (or square)”-shaped structure may be formed. As illustrated in FIG. 2, a part of the separators 12 and 14 has a structure isolated in a streak shape (streak-like isolated structure). The streak-like isolated structure has one or more passages that are isolated by the isolation means and communicate between the interior and exterior of the isolation means. The upper end parts of the separators 12 and 14 (end parts of the separators 12 and 14 located on the substrate holding means 13 side in the extending direction of the isolation means) are connected to the lower end parts of the separators (end parts located on the inner wall 111 side of the vacuum chamber 11 in the extending direction of the isolation means) via the streak-like isolated structure of the separators 12 and 14. The isolation means surrounds the film formation areas 20 and 40, which are thereby partitioned from other areas in the vacuum chamber 11. The streak-like isolated structure 12 is disposed in the vacuum chamber 11 so as to allow the film formation areas 20 and 40 to communicate with the exterior of the film formation areas 20 and 40.

In the present embodiment, the separators 12 and 14 are disposed in the vacuum chamber 11 so as to allow the film formation areas 20 and 40 to communicate with the exterior of the film formation areas 20 and 40, so that when the pressure in the film formation areas 20 and 40 becomes higher than that in the exterior of the film formation areas 20 and 40, the gas in the film formation areas 20 and 40 can be discharged via the separators 12 and 14, and the pressure in the film formation areas 20 and 40 can be reduced. Specifically, at least one of the separators 12 and 14 in the present embodiment is provided with a communication gap 122 that allows the film formation areas 20 and 40 to communicate with the exterior of the film formation areas 20 and 40. In the present embodiment, the communication gap 122 may be a slit, a through-hole, a gap, or the like, and it suffices that the communication gap 122 allows the film formation areas 20 and 40 to communicate with the exterior of the film formation areas 20 and 40.

Each of the separators 12 and 14 may be formed, for example, of a rectangular plate, the communication gap may be a plurality of through-holes provided in the rectangular plate, and the arrangement of the through-holes is not particularly limited. The through-holes may be oblique holes or straight holes, and are also not limited.

In the present embodiment, at least one of the separators 12 and 14 includes a plurality of baffles 121 arranged along the direction from the inner wall 111 of the vacuum chambers 11 to the substrate holding means 13. The communication gap 122 is located between two adjacent baffles 121. The communication gap 122 may be provided between each two adjacent baffles 121, but it suffices that the communication gap 122 exists between at least a pair of adjacent baffles 121.

Preferably, in the present embodiment, the two separators 12 and 14 may be each provided with a plurality of baffles 121. Each of the separators 12 and 14 is provided with the communication gap 122 between each two adjacent baffles 121. In the present embodiment, the baffles 121 may be in a shape of a rectangular plate, an elliptical plate, other polygonal plate, an (approximately) curved plate, or the like. Preferably, in the present embodiment, the baffles 121 may be rectangular plates from the viewpoints of convenience of manufacture and cost. Two adjacent baffles 121 may be or may not be in contact with each other and it suffices that a gap exists at least partially between two adjacent baffles 121. In an exemplary case, two adjacent baffles 121 are arranged in an “N” shape (cross section in the vertical plane parallel to the above axis Z), and two sides of a middle baffle 121 may be in contact with the baffles 121 in its vicinity. In another exemplary case, two or more adjacent baffles 121 may be arranged in a shape of “1 1 1” so that they are not in contact with each other.

Two adjacent baffles 121 may be arranged in parallel or may not necessarily be arranged in parallel, and it suffices that a gap exists between two adjacent baffles 121. The sides of the baffles 121 close to (or positioned in) the film formation areas 20 and 40 may be inner ends 121b (one end parts: the end parts near the film formation areas 20 and 40 are also referred to as the inner ends, which correspond to end parts located inside the boundary between portions isolated by the isolation means), and the sides away from the film formation areas 20 and 40 may be outer ends 121a (the other end parts: the end parts far from the film formation areas 20 and 40 are also referred to as the outer ends, which correspond to end parts located outside the boundary between portions isolated by the isolation means). With regard to a situation in which two adjacent baffles 121 are parallel to each other, the two adjacent baffles 121 may be parallel to each other in the extending direction from the inner ends 121b to the outer ends 121a. In this situation, the two adjacent baffles 121 are not in contact with each other.

With regard to a situation in which two adjacent baffles 121 may not be parallel to each other, the two adjacent baffles 121 may not be parallel to each other in the extending direction of the baffles 121 from the inner ends 121b to the outer ends 121a. In this situation, if the two adjacent baffles 121 extend with a long length, they may intersect with each other, but they may be or may not be in contact with each other depending on the length of the two adjacent baffles 121.

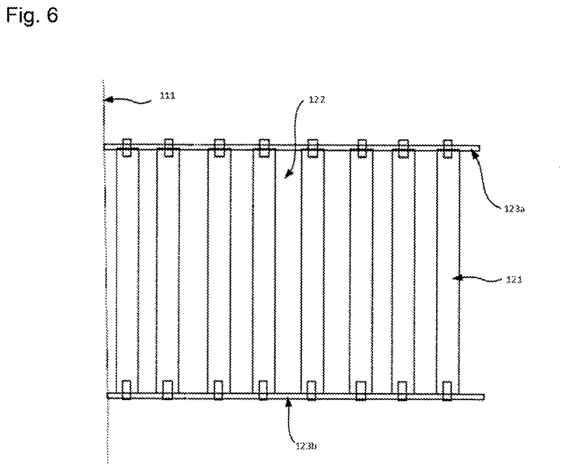

In the present embodiment, a number of baffles 121 are arranged in parallel along the direction from the inner wall 111 of the vacuum chamber 11 to the substrate holding means 13. The baffles 121 of the separators 12 and 14 are arranged parallel to each other, and a communication gap 122 is formed between two adjacent baffles 121. When the main surfaces of the baffles 121 are formed in a rectangular shape, the sides along the longitudinal direction of the main surfaces of the baffles 121 are in an orthogonal relationship with the extending direction of the isolation means (extending direction from the inner wall 111 toward the substrate holding means 13, right-left direction on the sheet plane of FIG. 6), and the transverse direction of the main surfaces of the baffles 121 are parallel to the extending direction of the isolation means. The communication gap 122 is a through-hole formed between two baffles 121.

The extending direction of the baffles 121 from the inner ends 121b to the outer ends 121a (which may be the longitudinal direction of the cross sections of the baffles 121 located in the horizontal plane orthogonal to the axis Z) may be parallel to the right-left direction in FIGS. 4 and 5 or may also form a certain angle with the right-left direction in FIGS. 4 and 5, and the extending direction of the baffles 121 is not limited at all in the present invention.

In the present embodiment, to further reduce the incident components in oblique directions (obliquely incident components) to improve the effect of reducing the scattering on the thin films, the baffle 121 are inclined toward the substrate holding means 13 from the outer ends 121a to the inner ends 121b. In this case, the baffles 121 have inclined surfaces behind which the substrates S face the film formation areas 20 and 40 so that the obliquely incident components are reduced. That is, the baffles 121 are inclined so that the main surfaces of the baffles 121 are aligned from the outer ends 121a toward the end parts (inner ends 121b) with respect to the substrates S in the back.

As illustrated in FIG. 5, the extending direction of the baffles 121 from the outer ends 121a to the inner ends 121b is set to have an angle with respect to the right-left direction in FIG. 5. Specifically, the inclination angle θ of the baffles 121 (angle of the main surfaces of the baffles 121 with respect to a plane along the inner wall 111) satisfies 0<θ≤90°. The angle between the main surface of each baffle 121 and a plane along the inner wall 111 is an acute angle.

As illustrated in FIG. 6, each of the separators 12 and 14 may further include a frame having two parallel frame plates 123a and 123b, one ends of which are fixed to the inner wall 111 of the vacuum chamber 11 while the other ends are free ends.

As illustrated in FIG. 6, the two frame plates 123a and 123b are installed in parallel at the upper and lower positions, and a number of baffles 121 are mounted in parallel on the two frame plates 123a and 123b and supported by the two frame plates 123a and 123b. The baffles 121 may be rotatably connected to the frame plates 123a and 123 so that the inclination angle of the baffled 121 can be adjusted.

In the separators 12 and 14, the distance between two adjacent baffles 121 (distance along the arrangement direction of the baffles 121) may be the same or may also be different. For example, the distance between two adjacent baffles 121 may increase or decrease in a stepwise manner along the arrangement direction, or the distance between two adjacent baffles 121 may not be the same, and is not particularly limited in the present invention.

In the present embodiment, preferably, the distance between two adjacent baffles 121 is the same. Specifically, the distance between two adjacent baffles 121 is smaller than the length from the inner ends 121b to the outer ends 121a of the baffles 121.

In the present embodiment, to prevent the interference with the movement of the substrate holding means 13 and the influence on the formation of thin films as described above, the distance from the inner end 121b of the baffle 121 closest to the substrate holding means 13 to the substrate holding means 13 is more than 0 and less than 0.9 times the distance from the targets 29 to the substrates S.

In the separators 12 and 14, the shapes of two adjacent baffles 121 may be the same or may also be different. For example, at least one parameter of the thickness, width, or height (length) of two adjacent baffles 121 may be different, or one baffle 121 may be a rectangular plate and the other baffle 121 may be a curved plate.

The width of the baffles 121 may be the length of cross sections of the baffles 121 when the baffles 121 are cut at a plane orthogonal to the axis Z of the baffle 121, which length may also be the length from the inner ends 121b to the outer ends 121a (or from the outer ends 121a to the inner ends 121b) of the baffles 121. The thickness of the baffles 121 may be the width of cross sections of the baffles 121 located on the horizontal plane orthogonal to the axis Z, which width may also be the distance between two side surfaces of a baffle 121 that have the maximum surface area and face each other. The height (length) of the baffles 121 may be the length of cross sections of the baffles 121 located on the horizontal plane orthogonal to the axis Z.

In the present embodiment, the length from the inner ends 121b to the outer ends 121a of at least two baffles 121 is the same or decreases along the direction from the targets 29 to the substrates S. That is, the width of at least two baffles 121 is the same or decreases along the direction from the targets 29 to the substrates S. Furthermore, the length of the baffles 121 from the inner ends 121b to the outer ends 121a is smaller than the width of the targets 29 or than the distance from the targets 29 to the substrates S.

In the present embodiment, at least a part of the main surface of at least one of the separators 12 and 14 is a rough surface. The rough surface can increase the microscopic irregular structure on the outer surfaces of the separators 12 and 14. As the inventors have proved by test, a shield having a rough surface is effective for suppressing the generation of the obliquely incident components in the vacuum chamber 11, and the surface structure having large irregularity can improve the adsorption effect on the scattering particles.

In addition or alternatively, the rough surface is formed by twin wire arc spray (TWAS), and the roughness of the rough surface is one tenth or less of the thickness of the twin wire arc spray treated layer. Among others, the side surfaces of the baffles 121 facing the film formation areas 20 and 40 are preferably processed to be rough surfaces so as to improve the effect of reducing the scattering on the thin films to the maximum extent.

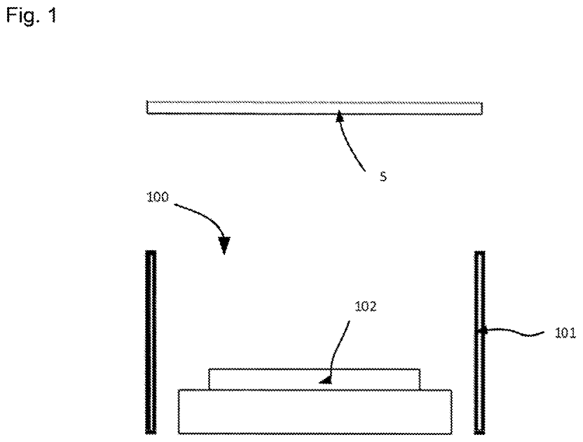

The film formation device as illustrated in FIG. 1 (conventional type, referred to as a comparative example) and the film formation device 1 illustrated in FIG. 2 (corresponding to an embodiment of the present invention) were employed to obtain a number of experimental example samples through installing the same number of substrates S on the substrate holding means 13 and repeating the sputtering performed in the film formation area 20 and the plasma exposure performed in the reaction area 60 under the same condition to form SiO₂ thin films having the same thickness on the substrates S. Chemically strengthened glass Gorilla 2 available from Corning (also referred to as Gorilla Glass) is used for all the (base material) substrates of the embodiment of the present invention and the comparative example. The surface roughness Ra of the substrates is 0.2 nm and the haze value is 0.06%. Antireflective films (coated films) are formed on the substrates using a RAS apparatus available from Shincron and the film thickness is about 500 nm.

The surface roughness and haze value of the SiO₂ thin films formed in the comparative example and the embodiment of the present invention were measured and compared. Among these, the roughness of each sample surface is measured in a measurement environment which is a tapping mode of DIMENSION Icon available from BRUKER, and the measurement area is 1 μm×1 μm. In addition, the haze value is measured using Haze meter NDH2000 available from NIPPON DENSHOKU INDUSTRIES CO., LTD. The results are listed in the following table.

TABLE 1

| | Surface roughness | |
|---|---|---|
| | Ra of | |
| | antireflective film | Haze |
| | (nanometer, nm) | value |
| Comparative example | 1.50 | 0.20 |
| Embodiment | 0.61 | 0.07 |

As found from the above results, the surface roughness of the comparative example (conventional example) was 0.95 nm, while in the embodiment of the present invention, 0.61 nm was shown. At the same time, the haze value was reduced from 0.20% to 0.07%. As understood from this, in the film formation device of the embodiment of the present invention, the surface roughness of the formed thin films is drastically reduced, the surfaces are smoother, and the effect of reducing the scattering on the thin films has been confirmed.

Digital values cited in this document include all lower and upper values increasing with one unit between the lower and upper limits and it suffices that at least two units of spacing exist between any lower value and any higher value. For example, if it is stated that the number of components of one type or the value of a process variable (such as a temperature, pressure, or time) is 1 to 90, preferably 20 to 80, and more preferably 30 to 70, it is intended to explain, for example, that values such as 15 to 85, 22 to 68, 43 to 51, or 30 to 32 are also explicitly listed in the description. For values less than one, one unit is properly considered to be 0.0001, 0.001, 0.01, or 0.1. These are merely examples for clear expression and it can be considered that all possible combinations of numerical values listed between the lowest and highest values are also explicitly stated in the description in a similar manner.

Unless otherwise stated, any of ranges includes the endpoints and all numerals between the endpoints. The term “about” or “approximately” used with a range is applicable to the two endpoints of the range. Thus, “about 20 to 30” is intended to cover “about 20 to about 30” and includes at least the specified endpoints.

All the disclosed text and references (including patent applications and publications) are described herein by reference for various purposes. The term “consisting essentially of” for describing a combination is considered to include the determined elements, components, parts, or steps and other elements, components, parts, or steps that do not substantially affect the basic novelty requirements of the combination. As for describing a combination of elements, components, parts, or steps herein using the term such as “comprise” or “comprising,” an embodiment consisting essentially of these elements, components, parts, or steps is also conceivable. It is intended that the term “can (may, be possible)” can be used thereby to explain that any attribute described with “can (may, be possible)” is selectable.

Two or more elements, components, parts, or steps can be provided by a single integrated element, component, part, or step. Alternatively, a single integrated element, component, part, or step can be divided into two or more separate elements, components, parts, or steps. The term “a (an)” or “one” disclosed to describe an element, component, part, or step does not exclude other elements, components, parts, or steps.

The above description can be considered to describe the illustration rather than for limitation. Various embodiments and various applications other than the provided examples will be apparent to a person skilled in the art when accessing the above description. Therefore the scope of the present teachings should not be determined with reference to the above description, but should be determined with reference to the appended claims and the entire scope of equivalents of these claims. For the purpose of being comprehensive, all the text and references (including patent applications and publications) are described herein by reference. Any aspect of the subject matter omitted in the claims but disclosed herein is not for abandoning the subject matter, and it should not be considered that the inventors do not consider the subject matter to be a part of the disclosed inventive subject matter.

### DESCRIPTION OF REFERENCE NUMERALS

1 Film formation device
2 Chemically strengthened glass, Gorilla, available from Corning
10 Vacuum pump
11 Vacuum chamber
12 Separator
13 Substrate holding means
14 Separator
16 Partitioning wall
20 Film formation area
21a Magnetron sputtering electrode
21b Magnetron sputtering electrode
23 AC power source
24 Transformer
25 Mass flow controller
26 Cylinder
29 Target
29a, 29b Target
40 Film formation area
60 Reaction area
67 Mass flow controller
68 Gas cylinder
80 Plasma source
89 AC power source
100 Film formation area
101 Separator
102 Target
111 Inner wall surface
121 Baffle
121a Outer end
121b Inner end
122 Communication gap

1-17. (canceled)

18. A film formation device comprising:
a vacuum chamber;
an evacuation mechanism communicating with an interior of the vacuum chamber;
a substrate holding means capable of holding a plurality of substrates;
a film formation area located in the interior of the vacuum chamber, the film formation area allowing sputtered particles to be emitted from a target by sputtering and arrive at the substrates; and
an isolation means located in the vacuum chamber, the isolation means isolating the film formation area from an area in the vacuum chamber, wherein
an electrode holding the target is provided on an inner wall of the vacuum chamber,
the isolation means has a mechanism for allowing the film formation area to communicate with an exterior of the film formation area, and
the isolation means extends, at a predetermined position of the inner wall on which the electrode is provided, from the predetermined position to the substrate holding means and surrounds the target in the film formation area.

19. The film formation device according to claim 18, wherein the isolation means is provided at a predetermined position of the inner wall of the vacuum chamber so that an extending direction of the isolation means is orthogonal to a direction along the inner wall.

20. A film formation device comprising:
a vacuum chamber;
an evacuation mechanism communicating with an interior of the vacuum chamber;
a substrate holding means capable of holding a plurality of substrates;
a film formation area located in the interior of the vacuum chamber, the film formation area allowing sputtered particles to be emitted from a target by sputtering and arrive at the substrates; and
an isolation means located in the vacuum chamber, the isolation means isolating the film formation area from an area in the vacuum chamber, wherein
the isolation means has a mechanism for allowing the film formation area to communicate with an exterior of the film formation area and includes two separators provided opposite to each other,
the film formation area is located between the two separators,
at least one of the separators is provided with a communication gap for communicating between the film formation area and the exterior of the film formation area, and
the at least one of the separators includes a plurality of baffles arranged along a direction from an inner wall of the vacuum chamber to the substrate holding means, and
the communication gap is located between adjacent two of the baffles.

21. The film formation device according to claim 20, wherein the plurality of baffles is arranged in parallel along the direction from the inner wall of the vacuum chamber to the substrate holding means.

22. The film formation device according to claim 20, wherein the baffles are inclined toward the substrate holding means from one end parts to other end parts of the baffles.

23. The film formation device according to claim 22, wherein an inclination angle θ of the baffles with respect to a plane along the inner wall of the vacuum chamber satisfies 0<θ≤90°.

24. The film formation device according to claim 20, wherein a length from one end parts to other end parts of the baffles is shorter than a width of the target or a distance from the target to the substrates.

25. The film formation device according to claim 20, wherein at least two of the baffles have an equal length from one end parts to other end parts of the baffles or reduce in size along a direction from the target to the substrates.

26. The film formation device according to claim 20, wherein a distance between adjacent two of the baffles is shorter than a length from one end parts to other end parts of the baffles.

27. The film formation device according to claim 20, wherein a distance between adjacent two of the baffles is equal.

28. The film formation device according to claim 20, wherein a distance from one end part of the baffle closest to the substrate holding means to the substrate holding means is more than 0 and less than 0.9 times a distance from the target to the substrates.

29. A film formation device comprising:
a vacuum chamber;
an evacuation mechanism communicating with an interior of the vacuum chamber;
a substrate holding means capable of holding a plurality of substrates;
a film formation area located in the interior of the vacuum chamber, the film formation area allowing sputtered particles to be emitted from a target by sputtering and arrive at the substrates; and
an isolation means located in the vacuum chamber, the isolation means isolating the film formation area from an area in the vacuum chamber, wherein
the isolation means has a mechanism for allowing the film formation area to communicate with an exterior of the film formation area and includes two separators provided opposite to each other,
the film formation area is located between the two separators, and
at least a part of a surface of at least one of the separators is a rough surface.

30. The film formation device according to claim 29, wherein the rough surface is formed by twin wire arc spray and roughness of the rough surface is one tenth or less of a thickness of a twin wire arc spray treated layer.
